(19) United States
(12) Patent Application Publication
(10) Pub. No.: US 2026/0239574 A1
(43) Pub. Date: Aug. 13, 2026

(54) GLOW PIT DEVICE WITH ELECTRONIC HEATING ASSEMBLY AND RELATED METHODS

(71) Applicant: ATLeisure, LLC, Atlanta, GA (US)

(72) Inventor: WILLIAM MARTIN BROWNE, ATLANTA, GA (US)

(21) Appl. No.: 19/537,057

(22) Filed: Feb. 11, 2026

Related U.S. Application Data
(60) Provisional application No. 63/757,534, filed on Feb. 12, 2025.
(60) Provisional application No. 63/853,969, filed on Jul. 30, 2025.

(51) Int. Cl. H05K 7/20

(52) U.S. Cl. CPC H05K 7/20563

(57) ABSTRACT

A glow pit device may include a first housing to rest on a floor and having a cavity, and defining annular openings. The glow pit device may include a second housing coupled to the first housing and having a translucent portion. The glow pit device may further include an electronics assembly having an electronics housing carried within the first housing, an electronic light source carried by the electronics housing, an audio output device carried by the electronics housing, and a controller carried by the electronics housing and coupled to the electronic light source and the audio output device. The controller may be configured to cause the electronic light source to transmit visual effects through the translucent portion, and cause the audio output device to generate an audio indication.

### RELATED APPLICATION

This application is based upon prior filed copending Application Nos. 63/757,534 filed Feb. 12, 2025, and 63/853,969 filed Jul. 30, 2025, the entire subject matter of which is incorporated herein by reference in its entirety.

### TECHNICAL FIELD

The present disclosure relates to the field of outdoor accessories, and, more particularly, to a glow pit device and related methods.

### BACKGROUND

Outdoor accessories and furniture is a robust and well developed industry. One popular class type in this category of products is the outdoor firepit, which provides warmth for outdoor gathering spaces. Broadly, there are combustive fire pits, which are quite common, and electronic fire pits. The combustive fire pits may comprise wood based fire pits and natural gas fire pits. Of course, with combustive fire pits, the user must periodically resupply fuel to the fire pit.

### SUMMARY

Generally, a glow pit device may include a first housing to rest on a floor and having a cavity therein, and defining a plurality of annular openings, and at least one electronic heating assembly carried by the first housing within the cavity and configured to generate heated air through the plurality of annular openings. The glow pit device also may include a second housing coupled to the first housing and comprising a translucent portion, an electronic light source adjacent to the translucent portion, and a controller coupled to the at least one electronic heating assembly and the electronic light source. The controller may be configured to cause the electronic light source to transmit visual effects through the translucent portion, and activate the at least one electronic heating assembly.

In particular, the second housing may comprise an inner housing, an outer housing adjacent to the inner housing and carrying the translucent portion, and a coupling interface coupling the inner housing and the outer housing together. The second housing may comprise a drain feature extending through the first housing and the second housing. The drain feature may include a drain passageway extending through the first housing and the second housing, and a pipe fluidly coupled to the drain passageway and extending outwardly from the second housing. The second housing may comprise a top cover over the inner housing and the outer housing.

The electronic light source may comprise a plurality of light emitting diode (LED) devices carried by the inner housing. In some embodiments, each of the plurality of LED devices may comprise an LED matrix assembly. The outer housing may comprise at least one vertical protrusion to abut the inner housing. The at least one vertical protrusion may comprise a first medial protrusion, and as second annular protrusion.

Further, the glow pit device may also comprise an audio output device coupled to the controller, and the controller may be configured to cause the audio output device to generate an audio indication. The at least one electronic heating assembly may comprise a plurality thereof, the plurality of electronic heating assemblies being carried by the first housing in a radially spaced apart arrangement.

Another aspect is directed to a glow pit device. The glow pit device may also include a first housing to rest on a floor and having a cavity therein, and defining a plurality of annular openings, and a second housing coupled to the first housing and comprising a translucent portion. The glow pit device may further comprise an electronics assembly comprising an electronics housing carried within the first housing, at least one electronic light source carried by the electronics housing, an audio output device carried by the electronics housing, and a controller carried by the electronics housing and coupled to the at least one electronic light source and the audio output device. The controller may be configured to cause the at least one electronic light source to transmit visual effects through the translucent portion, and cause the audio output device to generate an audio indication.

In some embodiments, the electronics assembly may comprise an electronic heating assembly adjacent to the electronics housing. The electronic heating assembly may include at least one heating device, and a thermal reflector adjacent to the at least one heating device and configured to direct thermal radiation through the plurality of annular openings. The controller may be coupled to the electronic heating assembly and configured to activate the at least one heating device.

Also, the thermal reflector may comprise an annular-shaped thermal reflector, and the at least one heating device may comprise a plurality of heating devices carried by the annular-shaped thermal reflector in a radially spaced apart arrangement. The at least one electronic light source may be carried by an upper surface of the electronics housing.

Yet another aspect is directed to a method for making a glow pit device. The method may comprise forming a first housing to rest on a floor, the first housing having a cavity therein, and defining a plurality of annular openings, and coupling a second housing to the first housing, the second housing comprising a translucent portion. The method may also include positioning an electronics assembly within the first housing. The electronics assembly may include an electronics housing carried within the first housing, at least one electronic light source carried by the electronics housing, an audio output device carried by the electronics housing, and a controller carried by the electronics housing and coupled to the at least one electronic light source and the audio output device. The controller may be configured to cause the at least one electronic light source to transmit visual effects through the translucent portion, and cause the audio output device to generate an audio indication.

### BRIEF DESCRIPTION OF THE DRAWINGS

FIG. 1 is a perspective view of a glow pit device, according to a first example embodiment of the present disclosure.

FIG. 2A is an exploded view of a second housing from the glow pit device of FIG. 1.

FIG. 2B is a cross-sectional view of the second housing from the glow pit device of FIG. 1 along line 2B-2B.

FIG. 2C is a bottom plan view of the second housing from the glow pit device of FIG. 1.

FIG. 2D is an enlarged cross-sectional view of the second housing from the glow pit device of FIG. 1 along line 2B-2B.

FIG. 3A is a perspective view of a first housing from the glow pit device of FIG. 1 without the second housing coupled thereto.

FIG. 3B is another perspective view of the first housing from the glow pit device of FIG. 1 without the second housing coupled thereto.

FIG. 3C is a perspective view of a floor plate from the first housing from the glow pit device of FIG. 1.

FIG. 3D is a top plan view of the first housing from the glow pit device of FIG. 1.

FIG. 3E is a side view of the first housing from the glow pit device of FIG. 1.

FIGS. 4-5 are images of second and third example embodiments of the glow pit device, according to the present disclosure.

FIG. 6 is a perspective view of a fourth example embodiment of the glow pit device, according to the present disclosure.

FIG. 7A is a schematic cutaway view of the glow pit device of FIG. 6.

FIG. 7B is a schematic cutaway view of an inner bowl from the glow pit device of FIG. 6.

FIG. 7C is an enlarged cutaway view of the inner bowl from the glow pit device of FIG. 6.

FIGS. 7D & 7E are perspective views of the inner bowl from the glow pit device of FIG. 6.

FIG. 7F is an enlarged cutaway view of the inner bowl from the glow pit device of FIG. 6.

FIG. 7G is another enlarged cutaway view of a drain feature for the inner bowl from the glow pit device of FIG. 6.

FIGS. 8-9 are perspective views of the second housing from the glow pit device of FIG. 6.

FIGS. 10A-10E are enlarged cross-sectional views of a connection between the inner bowl and the outer bowl from the glow pit device of FIG. 6.

FIG. 11A is a perspective view of the first housing from the glow pit device of FIG. 6.

FIG. 11B is a bottom plan view of the first housing from the glow pit device of FIG. 6.

FIG. 11C is an exploded view of the first housing from the glow pit device of FIG. 6.

FIG. 12A is a perspective view of the first housing in a fifth example embodiment of the glow pit device, according to the present disclosure.

FIG. 12B is an exploded view of the first housing from the glow pit device of FIG. 12A.

### DETAILED DESCRIPTION

The present disclosure will now be described more fully hereinafter with reference to the accompanying drawings, in which several embodiments of the invention are shown. This present disclosure may, however, be embodied in many different forms and should not be construed as limited to the embodiments set forth herein. Rather, these embodiments are provided so that this disclosure will be thorough and complete, and will fully convey the scope of the present disclosure to those skilled in the art. Like numbers refer to like elements throughout, and base 100 reference numerals are used to indicate similar elements in alternative embodiments.

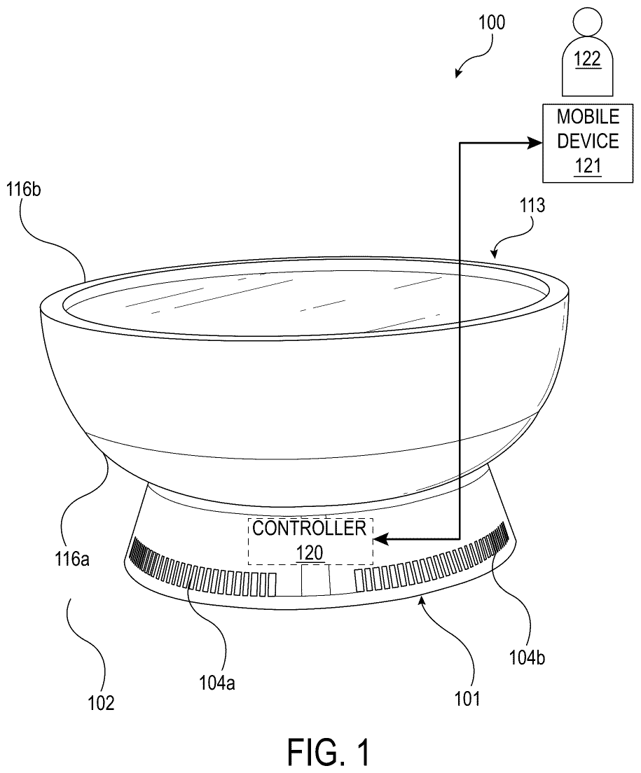

Referring initially to FIGS. 1-3E, a glow pit device 100 according to the present disclosure is now described. The glow pit device 100 illustratively includes a first housing 101 to rest on a floor 102 and having a first cavity 103 therein. The first housing 101 illustratively defines a plurality of sets of annular openings 104a-104d, and an electronic heating assembly 105 carried by the first housing within the first cavity 103. In the illustrated embodiment, each set of annular openings 104a-104d comprises a row of aligned slots with curved ends. In other embodiments, the sets of annular openings 104a-104d may have a different arrangement/number/shape.

The electronic heating assembly 105 illustratively includes a plurality of heating devices 106a-106d. For example, each of the plurality of heating devices 106a-106d may comprise a positive-temperature-coefficient (PTC) heating element plurality of heating devices 106a-106d (electrical resistive heater) with a power in a range of 200-500 Watts. Helpfully, this maintains the total amperage under 15 amps within a typical 120 volt power supply.

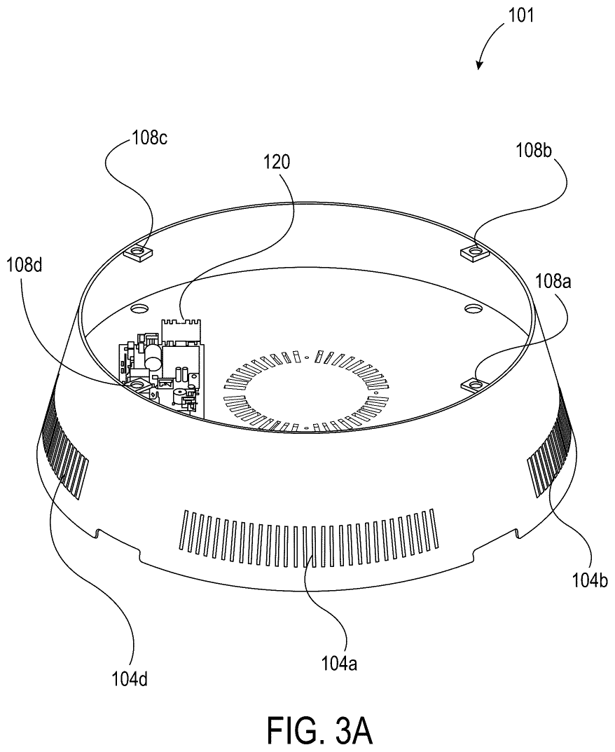

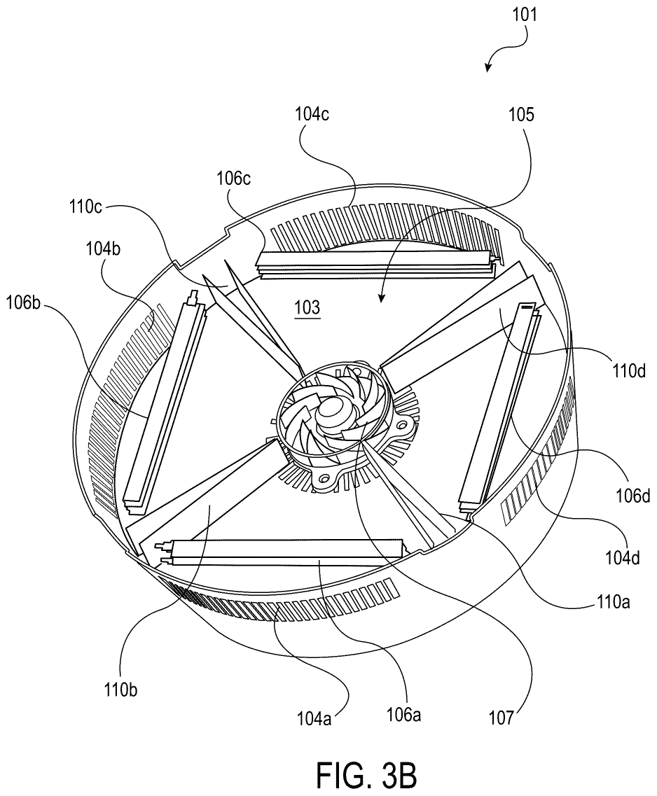

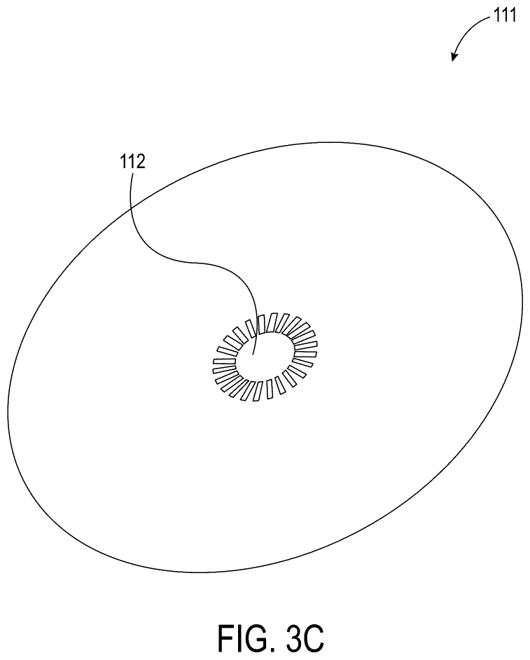

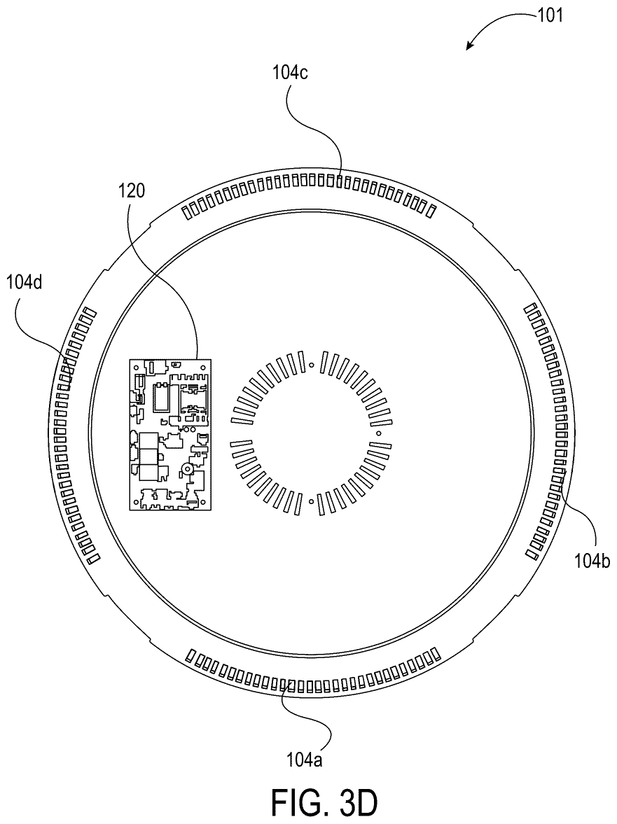

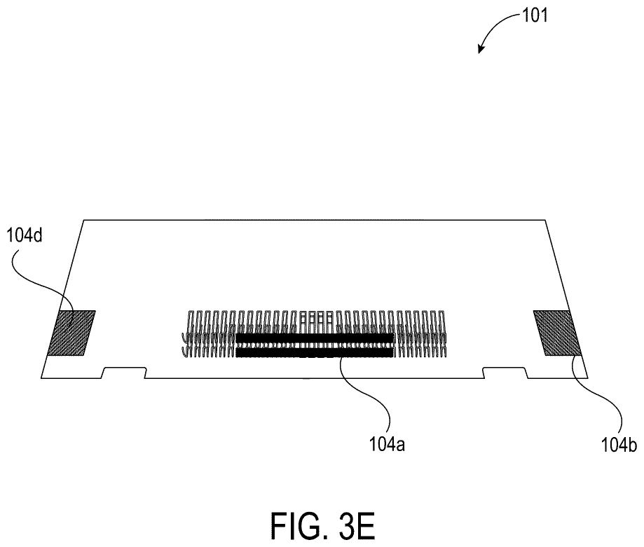

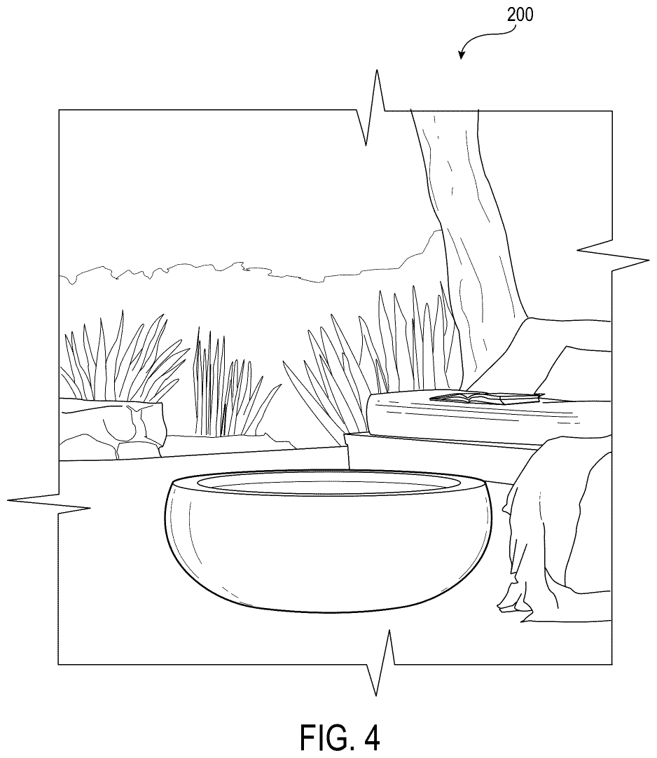

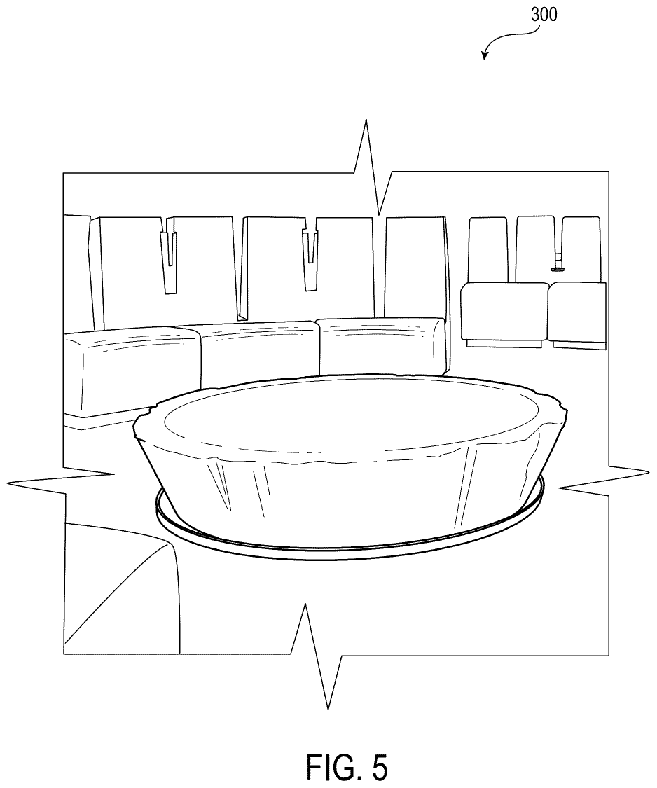

As perhaps best seen in FIG. 3B, the plurality of heating devices 106a-106d is arranged and aligned with the plurality of sets of annular openings 104a-104d. The electronic heating assembly 105 illustratively includes a positive pressure source 107 (e.g., illustrated fan) adjacent to the plurality of heating devices 106a-106d and configured to force heated air through the sets of annular openings 104a-104d. In particular, the positive pressure source 107 is positioned at the center of the first housing 101 and between both pairs of the plurality of heating devices 106a-106d. Further, first housing 101 illustratively includes air diverters 110a-110d configured to direct and route an output of the positive pressure source 107 to the plurality of sets of annular openings 104a-104d. As perhaps best seen in FIG. 3A, the first housing 101 illustratively includes a first plurality of mounting passageways 108a-108d.

Referring in particular to FIG. 3C, the glow pit device 100 illustratively includes a floor plate 111 to be received by the first housing 101 and to cover the first cavity 103. To match the shape of the first housing 101, the floor plate 111 is illustratively circle-shaped, but may vary in shape in correspondence with the first housing. Also, the floor plate 111 illustratively includes an inlet grate 112 aligned with the positive pressure source 107 and configured to permit airflow therethrough.

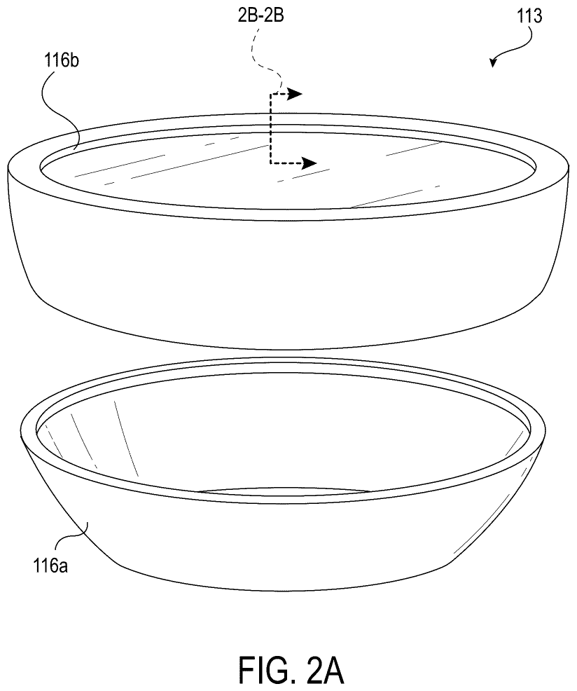

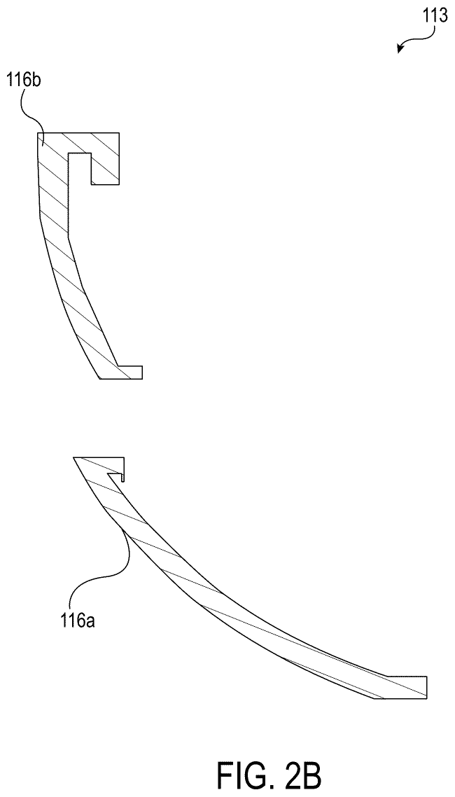

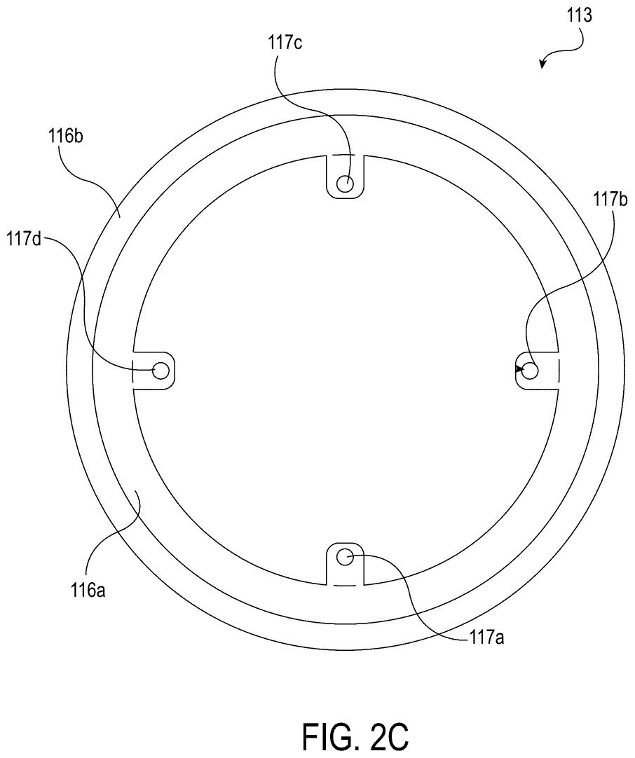

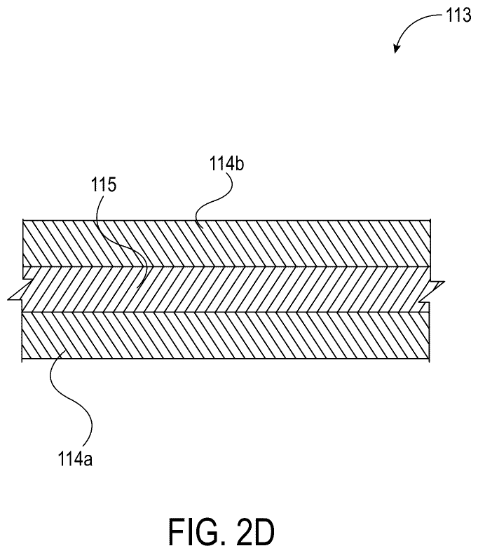

As perhaps best seen in FIGS. 2A-2D, the glow pit device 100 illustratively includes a second housing 113 coupled to the first housing 101 and comprising first and second translucent base layers 114a-114b, and an electronic light source layer 115 carried by and being between the first and second translucent base layers. The electronic light source layer 115 is configured to generate visual effects. The second housing 113 illustratively includes first and second sections 116a-116b configured to fit at annular edges thereof. The second housing 113 illustratively has a shape of a partial sphere, but may have other shapes in other embodiments. As perhaps best seen in FIG. 2C, the first section 116a illustratively includes a second plurality of mounting passageways 117a-117d to be aligned with the first plurality of mounting passageways 108a-108d. As will be appreciated, the first housing 101 and the second housing 113 are coupled together via a plurality of fasteners positioned respectively through the first plurality of mounting passageways 108a-108d and the second plurality of mounting passageways 117a-117d.

The glow pit device may further include a controller 120 coupled to the electronic heating assembly 105 and the electronic light source layer 115. The first housing 101 may comprise a rigid material with sufficient mechanical strength to support the second housing 113 and with sufficient heat resistance, for example, a metallic material such as aluminum. The second housing 113 may comprise any rigid material with the needed transparency needed to permit light transmission, for example, polymer plastic.

In some embodiments, the glow pit device 100 may comprise an audio output device carried by either the first housing 101 or the second housing 113 coupled to the controller 120 and configured to generate audio output. The audio output device may comprise a Bluetooth enabled device configured to be controlled by a mobile device 121 of the user 122. In these applications, the user 122 may use a mobile application to communicate with and control the glow pit device 100. In particular, the visual effects generated by the electronic light source layer 115 and the audio output of the audio output device may be controlled by the user 122. In some embodiments of the glow pit device 200, 300, the user 122 can select for a wide range of visual effects using the mobile application.

Advantageously, the glow pit device 100 may provide for controllable and safe heat for the user 122 in outdoor or indoor applications. Further, since the glow pit device 100 may maintain a current budget below 15 amps, it can be used within a typical residential power system. Also, the user 122 may control the heat level, the visual effects, and the audio output conveniently through the mobile application.

Another aspect is directed to a method for making a glow pit device 100. The method comprises forming a first housing 101 to rest on a floor 102 and having a first cavity 103 therein, and defining a plurality of sets of annular openings 104a-104d, and coupling an electronic heating assembly 105 to be carried by the first housing within the first cavity. The electronic heating assembly 105 includes a plurality of heating devices 106a-106d, and a positive pressure source 107 adjacent to the plurality of heating devices and configured to force heated air through the plurality of sets of annular openings 104a-104d. The method comprises coupling a second housing 113 to the first housing 101 and comprising first and second translucent base layers 114a-114b, and an electronic light source layer 115 carried by and being between the first and second translucent base layers. The electronic light source layer 115 is configured to generate visual effects. The method also includes coupling a controller 120 to the electronic heating assembly 105 and the electronic light source layer 115.

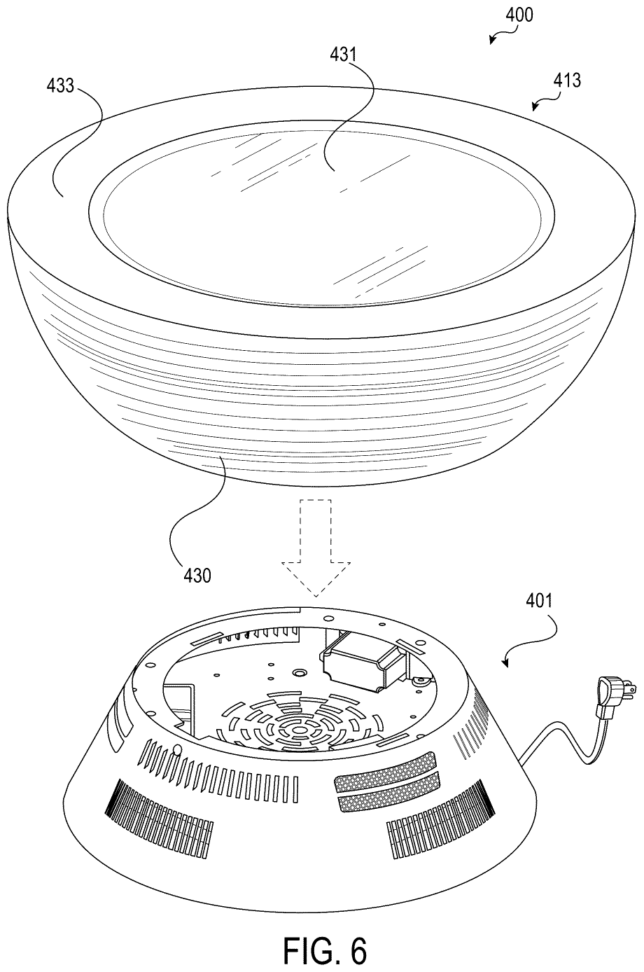

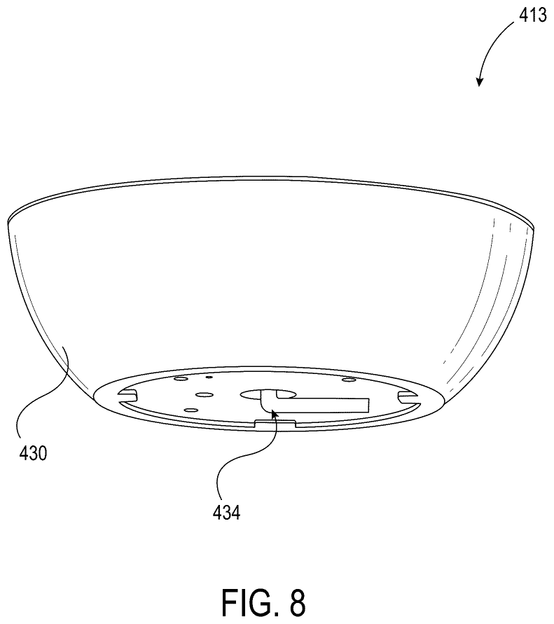

Referring now additionally to FIGS. 6, 7A-7G, 8-9, 10A-10E, & 11A-11C, another embodiment of the glow pit device 400 is now described. In this embodiment of the glow pit device 400, those elements already discussed above with respect to FIGS. 1-3E are incremented by 300 and most require no further discussion herein. This embodiment differs from the previous embodiment in that this glow pit device 400 illustratively includes the second housing 413 comprising an outer bowl 430 (outer housing), an inner bowl 431 (inner housing) received by the outer bowl, a coupling interface 432 coupling the inner bowl and the outer bowl, and a top cover 433 over the inner bowl and the outer bowl. Although the top cover 433 is illustratively ring-shaped or annular-shaped to define a medial opening therein, it should be appreciated that in other embodiments, the top cover may have other shapes. For example, the top cover 433 may be contiguous and cover the entire upper area above the second housing 413. The second housing 413 also includes a drain feature 434 extending through the inner bowl 431 and the outer bowl 430.

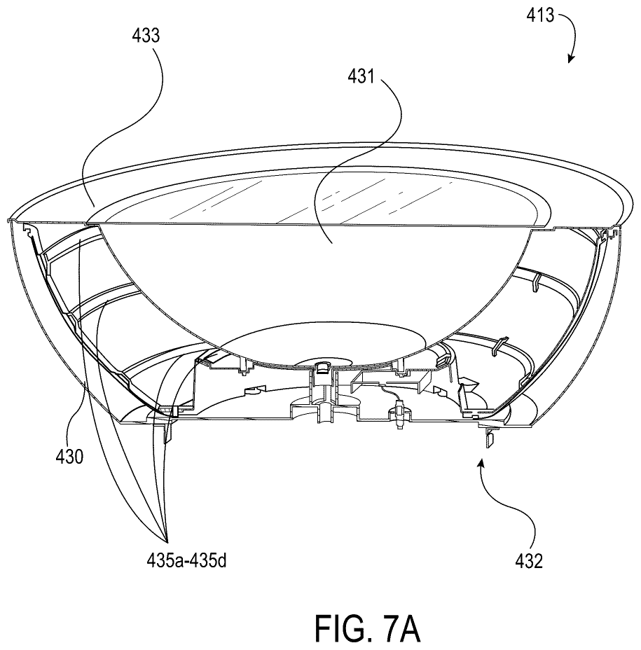

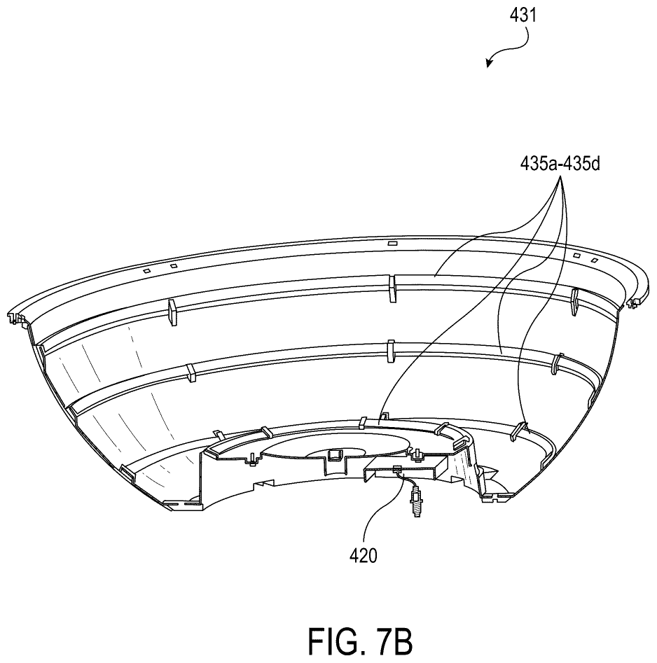

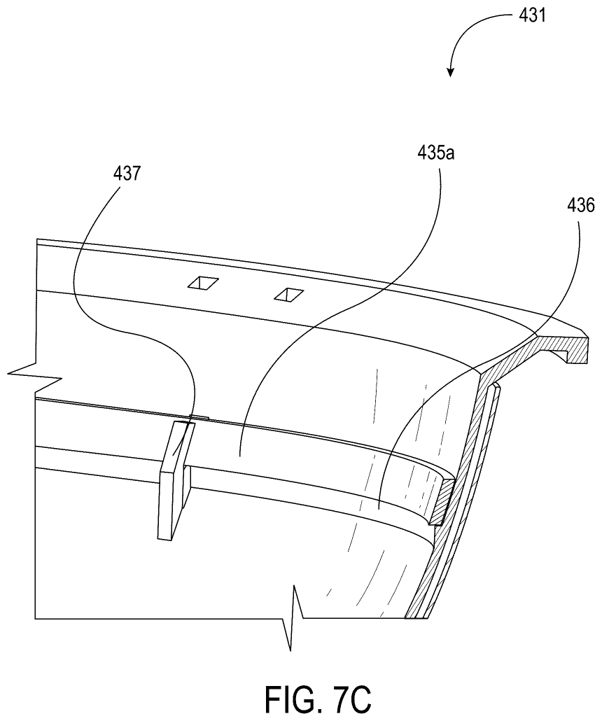

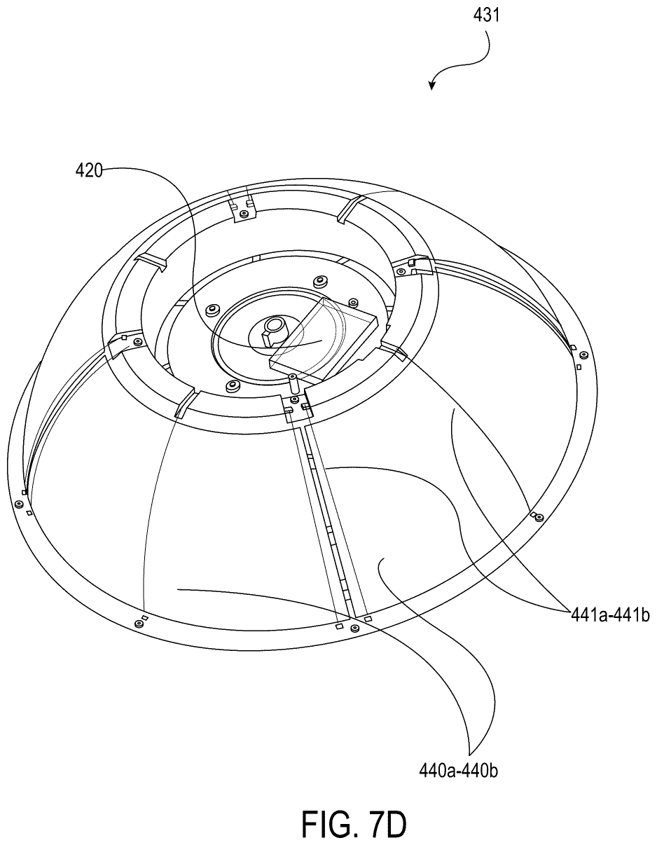

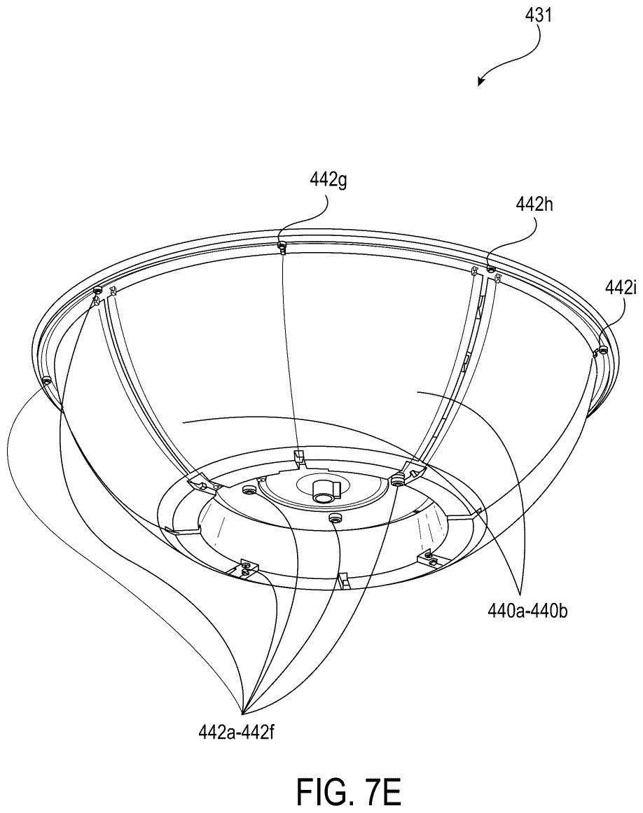

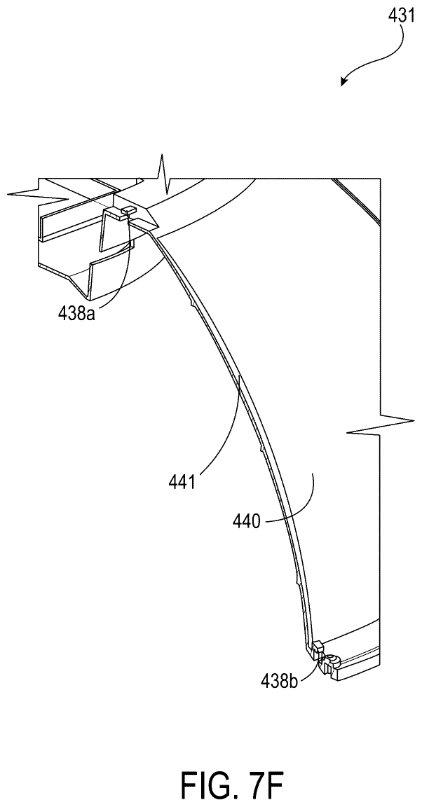

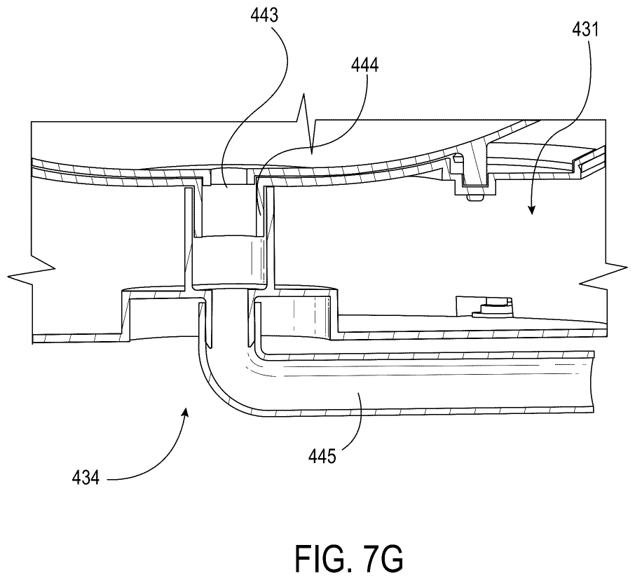

The second housing 413 illustratively includes a plurality of light emitting diode (LED) light strips 435a-435d carried by the inner bowl 431, and a controller 420 carried by the inner bowl 431 and configured to selectively enable the plurality of LED light strips. As perhaps best seen in FIG. 7B, each of the plurality of LED light strips 435a-435d is faced inward. The inner bowl 431 illustratively comprises a plurality of annular ledges 436 respectively supporting the plurality of LED light strips 435a-435d, and vertical arms 437 retaining the plurality of LED light strips 435a-435d on respective annular ledges. Further, in some embodiments, an adhesive layer may alternatively or additionally be positioned between each of the plurality of LED light strips 435a-435d and adjacent portions of the inner bowl 431.

As perhaps best seen in FIGS. 7D-7F, the inner bowl 431 illustratively comprises a plurality of LED matrix board assemblies 440a-440b carried by an outer surface of the inner bowl and facing outward, and a plurality of vertical straps 441a-441b for retaining the plurality of LED matrix board assemblies to the outer surface. Further, in some embodiments, an adhesive layer may be alternatively or additionally positioned between each of the plurality of LED matrix board assemblies 440a-440b and adjacent portions of the inner bowl 431. The plurality of vertical straps 441a-441b may prevent peripheral edges of the plurality of LED matrix board assemblies 440a-440b from lifting and delaminating, and are coupled at respective ends 438a-438b of the inner bowl 431. In FIG. 7E, the inner bowl and the outer bowl are coupled together via a plurality of fasteners 442a-442i, and a plurality of rubber gaskets thereon to prevent corrosion.

In FIG. 7G, the drain feature 434 is shown in detail. The drain feature 434 illustratively includes an opening 443 (drain passageway) extending through the inner bowl 431 and the outer bowl 430, a sealing ring 444 extending axially downward into the opening, and an L-shaped pipe 445 fluidly coupled to the opening and configured to direct drained fluid outside the glow pit device 400. In some embodiments, the glow pit device 400 may comprise a drainage plug for the opening 443, permitting the inner bowl 431 to be used as an ice cooler. Also, the inner bowl 431 and the outer bowl 430 illustratively have sloped bottom surfaces to urge drainage to the opening 443.

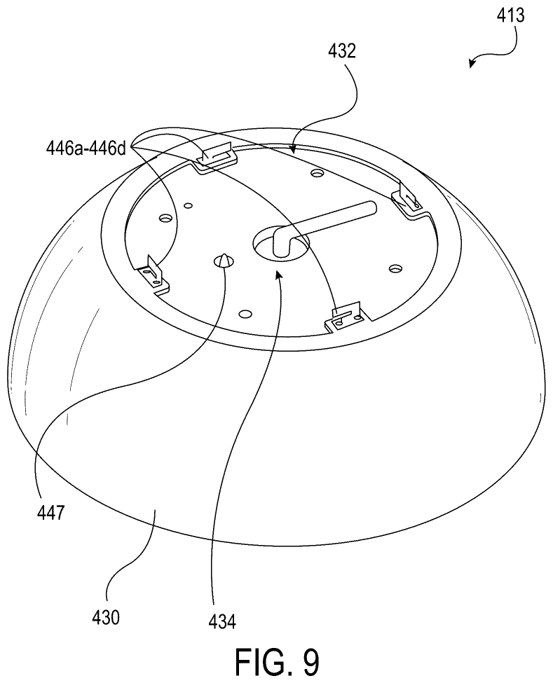

In FIG. 9, the outer bowl 430 illustratively includes a plurality of interface locking pins 446a-446d, which engage with respective openings 448a-448d in the first housing 401. The inner bowl 431 and the outer bowl 430 illustratively include a wire opening 447 for an electrical coupling between the controller 420 and the plurality of LED light strips 435a-435d and the plurality of LED matrix board assemblies 440a-440b.

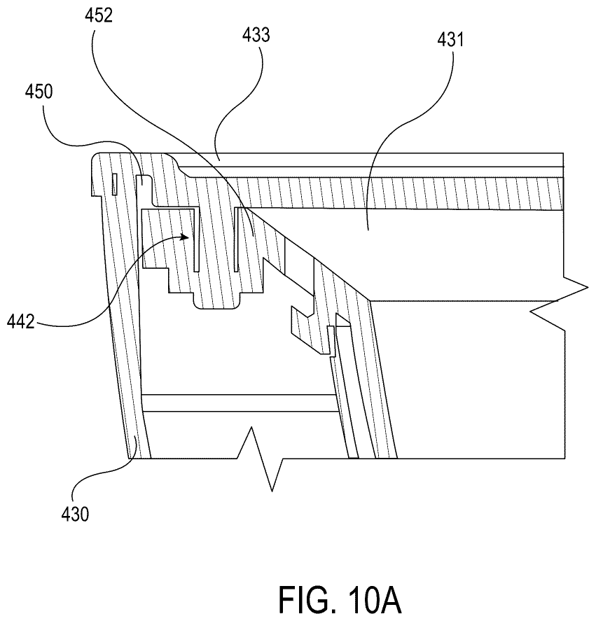

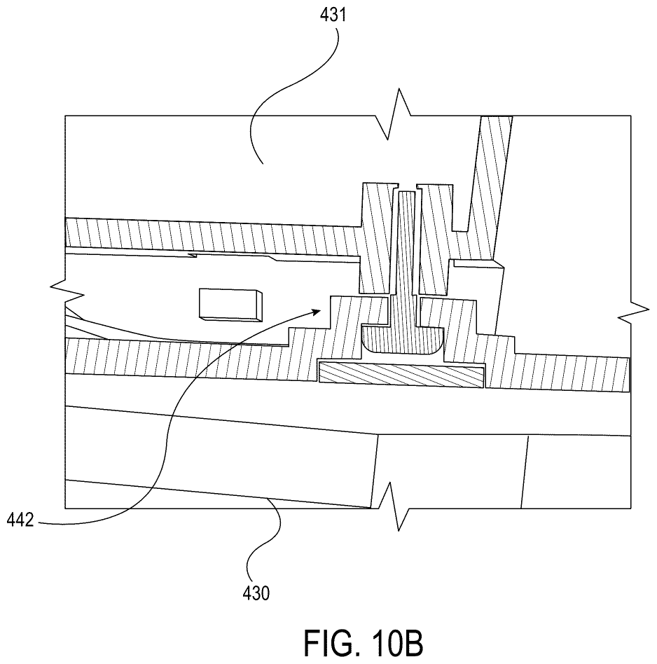

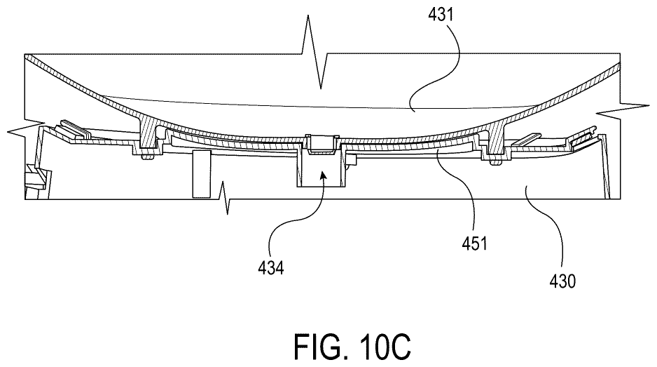

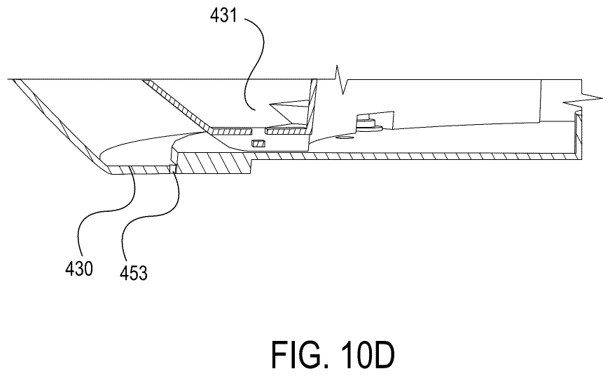

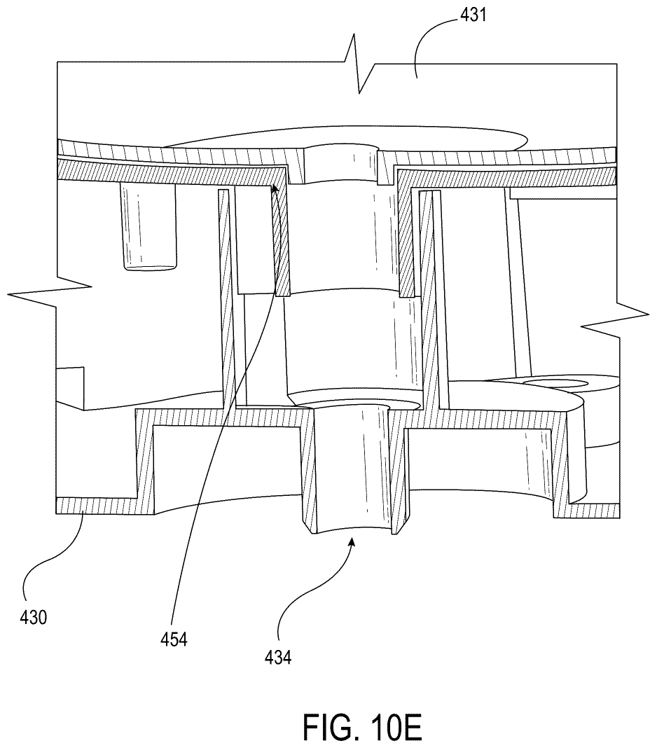

In FIG. 10A, the glow pit device 400 illustratively includes an annular sealing strip 450 between the inner bowl 431 and the outer bowl 430, which can effectively prevent water vapor from entering the inner basin. The inner bowl 431 and the outer bowl 430 are connected by a snap-fit design.

In FIGS. 10A & 10C, the outer bowl 430 illustratively comprises a medial vertical protrusion 451 extending from the outer bowl to support and abut the inner bowl 431, and an annular vertical protrusion 452 extending from the outer bowl to support and abut the inner bowl. Helpfully, this helps support greater weight placed upon the top cover 433. In FIG. 10D, the outer bowl 430 illustratively comprises an annular drain slot 453. Also, the peripheral bottom surfaces of the outer bowl 430 are sloped towards the annular drain slot 453. As perhaps best seen in FIG. 10E, the inner bowl 431 and the outer bowl 430 illustratively include aligned slots/openings 454 to ensure an accurate fit.

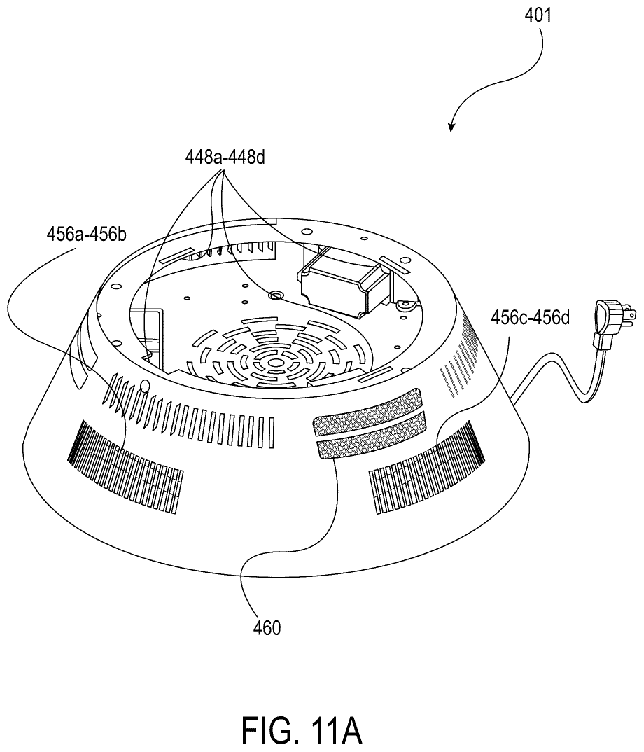

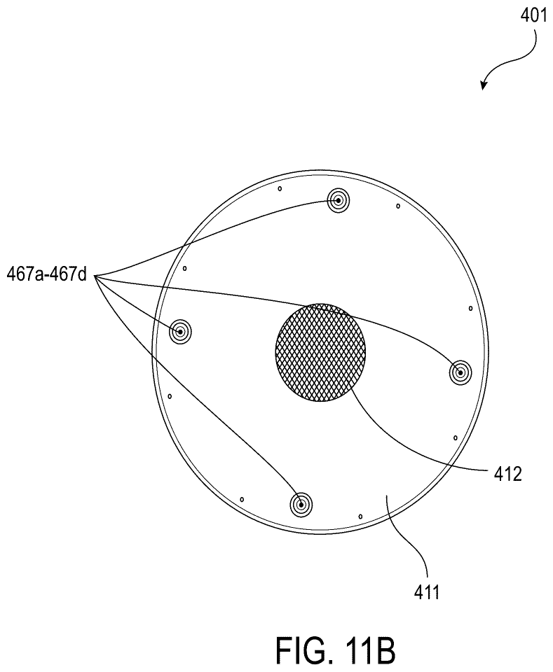

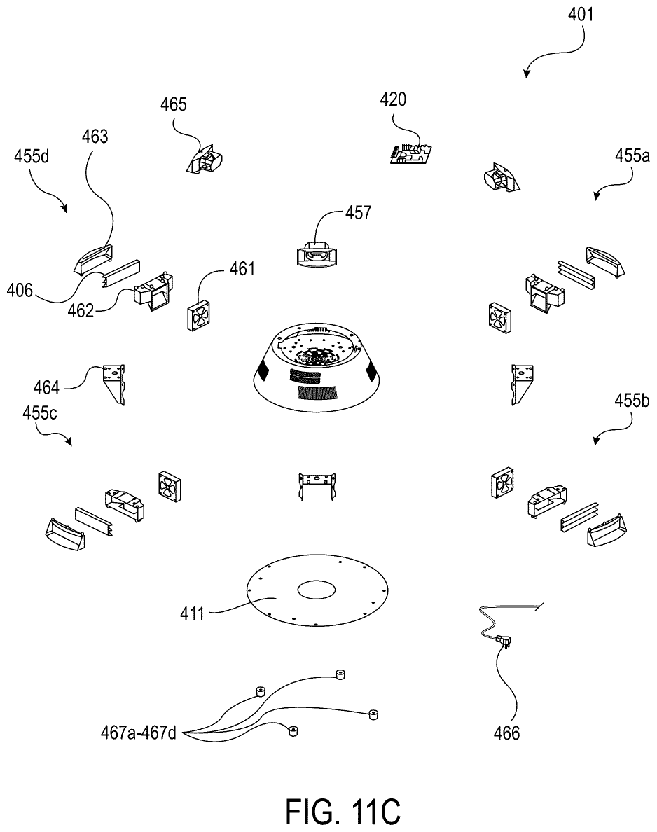

Referring to FIGS. 11A-11C, the first housing 401 illustratively includes a plurality of fan assemblies 455a-455d (electronic heating assembly). The fan assemblies 455a-455d are configured to drive heated air outward to the user through a plurality of heated air outlets 456a-456d. The glow pit device 400 illustratively includes a speaker 457 carried by the first housing 401, coupled to the controller 420, and configured to output audio indications (e.g., ambient music) through a speaking opening 460 in the first housing.

Each of the plurality of fan assemblies 455a-455d sequentially comprises a fan 461 coupled to the controller 420, an inner fan cover 462, a heating device 406, an outer fan cover 463, an inner fan frame 464, and a speaker grill cover 465 on an outer surface of the first housing 401. The glow pit device 400 illustratively includes a power cord 466 configured to be plugged into a power receptacle and powering the controller 420 and other powered components, and a plurality of feet 467a-767d carried by the floor plate 411.

It should be appreciated the outer bowl 430 substantially (i.e., ≥50% of surface area) comprises translucent material (translucent portion). Because of the translucent nature of the outer bowl 430, the light from the LED matrix board assemblies 440a-440b transmits through the outer bowl 430, which is visible to the user. Further, the top cover 433 may substantially (i.e., ≥50% of surface area) comprises translucent material (translucent portion). Because of the translucent nature of the top cover 433, the light from the plurality of LED light strips 435a-435d transmits through the top cover 433, which is visible to the user.

The second housing 413 may comprise a rigid material with required translucent properties. For example, the second housing 413 may comprise a polymer plastic material. The first housing 401 also may comprise a rigid material with heat resistance. For example, the first housing 401 may comprise one or more of a polymer material, and a metallic material.

Also, in some embodiments (See, e.g., FIGS. 1-3E), the glow pit device 400 may comprise a wireless transceiver coupled to the controller 420 and configured to communicate with an external device (e.g., remote control device, mobile device, tablet computing device) associated with the user. The wireless transceiver and the controller 420 are configured to receive commands from the external device for controlling the activation of the plurality of fan assemblies 455a-455d, the plurality of LED matrix board assemblies 440a-440b, the plurality of LED light strips 435a-435d, and the speaker 457. In some embodiments, the wireless transceiver and the controller 420 may be integrated within a same device, and in other embodiments, the wireless transceiver and the controller may be discrete components.

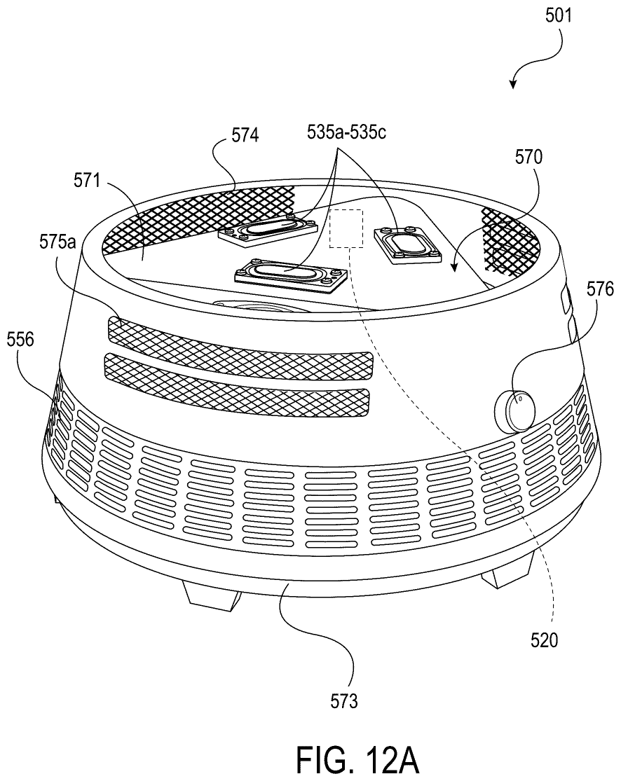

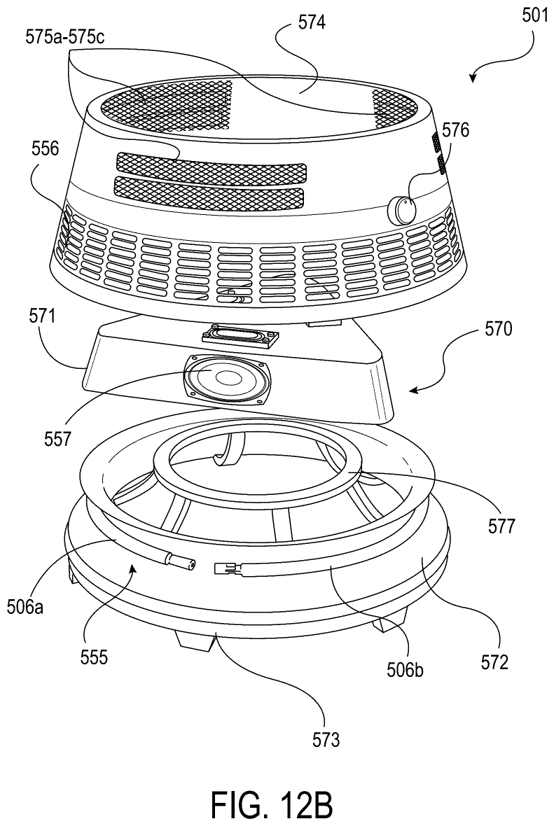

Referring now additionally to FIGS. 12A-12B, another embodiment of the glow pit device 500 is now described. In this embodiment of the glow pit device 500, those elements already discussed above with respect to FIGS. 1-3E are incremented by 400 and most require no further discussion herein. This embodiment differs from the previous embodiment in that this glow pit device 500 illustratively includes a first housing 501 to rest on a floor and having a cavity therein, and defining a plurality of annular openings 556, and a second housing coupled to the first housing and comprising a translucent portion. Although not depicted, the second housing may have a structure similar to the embodiments discussed hereinabove.

The glow pit device 500 illustratively comprises an electronics assembly 570 having an electronics housing 571 carried within the first housing 501, a plurality of electronic light sources 535a-535c carried by the electronics housing, an audio output device 557 carried by the electronics housing, and a controller 520 carried by the electronics housing and coupled to the plurality of electronic light sources and the audio output device. The electronic housing 571 illustratively has a triangle shape for presenting all sides with a facet, and it should be appreciated that although only one audio output device 557 is shown, each of the facets comprises an individual audio output device 557 (i.e., three audio output devices).

The controller 520 is configured to cause the plurality of electronic light sources 535a-535c to transmit visual effects through the translucent portion, and cause the audio output device 557 to generate an audio indication. In the illustrated embodiment, the plurality of electronic light sources 535a-535c are carried by an upper surface of the electronics housing 571. Helpfully, this permits the plurality of electronic light sources 535a-535c to transmit visual effects into the second housing.

In the illustrated embodiment, the second housing may have a structure similar to the embodiments discussed hereinabove without integrated electronic light devices/layers in the second housing (i.e., the light emitting devices from the sound housing are omitted). Here, the visual effects are completely generated from the first housing 501 and transmitted into the second housing. Of course, in other embodiments, the electronics assembly 570 may comprise one or more wires for coupling the controller 520 to the additional light emitting devices in the second housing.

Also, the electronics assembly 570 illustratively comprises an electronic heating assembly 555 adjacent to the electronics housing 571. The electronic heating assembly 555 includes a plurality of heating devices 506a-506b, and a thermal reflector 572 adjacent to the plurality of heating devices and configured to direct thermal radiation through the plurality of annular openings 556. Here, the plurality of annular openings 556 is arranged as a two-dimensional grid of elongate openings with curved ends. The controller 520 is coupled to the electronic heating assembly 555 and configured to activate the plurality of heating devices 506a-506b. Also, the thermal reflector 572 illustratively comprises an annular-shaped thermal reflector, and the plurality of heating devices 506a-506b is carried by the annular-shaped thermal reflector in a radially spaced apart arrangement. Helpfully, this embodiment omits the positive pressure source approach of the prior embodiments, which reduces power consumption. As will be appreciated, this maintains a needed power budget for allowing for safety certification, for example, UL certification, which is required for most consumer applications.

As perhaps best seen in FIG. 12B, the first housing 501 illustratively comprises an inner housing 573, and an outer housing 574 defining the annular openings 556. The inner housing 573 comprises a medial platform 577 to support and carry the electronics assembly 570. Also, the outer housing 574 defines speaker openings 575a-575c in a radially spaced arrangement. Also, the glow pit device 500 illustratively comprises a control input 576 (e.g., a rotary button) carried by the outer housing and coupled to the controller 520. The control input 576 is configured to permit user control of the electronic heating assembly 555.

Yet another aspect is directed to a method for making a glow pit device 500. The method comprises forming a first housing 501 to rest on a floor, the first housing having a cavity therein, and defining a plurality of annular openings 556. The method also includes coupling a second housing to the first housing, the second housing comprising a translucent portion. The method also includes positioning an electronics assembly 570 within the first housing 501. The electronics assembly 570 includes an electronics housing 571 carried within the first housing 501, a plurality of electronic light sources 535a-535c carried by the electronics housing, an audio output device 557 carried by the electronics housing, and a controller 520 carried by the electronics housing and coupled to the plurality of electronic light sources and the audio output device. The controller 520 is configured to cause the plurality of electronic light sources 535a-535c to transmit visual effects through the translucent portion, and cause the audio output device 557 to generate an audio indication.

It should be appreciated that features from each of the glow pit devices 100, 200, 300, 400, 500 may be combined with each other. Many modifications and other embodiments of the present disclosure will come to the mind of one skilled in the art having the benefit of the teachings presented in the foregoing descriptions and the associated drawings. Therefore, it is understood that the present disclosure is not to be limited to the specific embodiments disclosed, and that modifications and embodiments are intended to be included within the scope of the appended claims.

1. A glow pit device comprising:
a first housing to rest on a floor and having a cavity therein, and defining a plurality of annular openings;
at least one electronic heating assembly carried by the first housing within the cavity and configured to generate heated air through the plurality of annular openings;
a second housing coupled to the first housing and comprising a translucent portion;
an electronic light source adjacent to the translucent portion; and
a controller coupled to the at least one electronic heating assembly and the electronic light source and configured to
cause the electronic light source to transmit visual effects through the translucent portion, and
activate the at least one electronic heating assembly.

2. The glow pit device of claim 1 wherein the second housing comprises an inner housing, an outer housing adjacent to the inner housing and carrying the translucent portion, and a coupling interface coupling the inner housing and the outer housing together.

3. The glow pit device of claim 2 wherein the second housing comprises a drain feature extending through the first housing and the second housing.

4. The glow pit device of claim 3 wherein the drain feature comprises a drain passageway extending through the first housing and the second housing, and a pipe fluidly coupled to the drain passageway and extending outwardly from the second housing.

5. The glow pit device of claim 2 wherein the second housing comprises a top cover over the inner housing and the outer housing.

6. The glow pit device of claim 2 wherein the electronic light source comprises a plurality of light emitting diode (LED) devices carried by the inner housing.

7. The glow pit device of claim 6 wherein each of the plurality of LED devices comprises an LED matrix assembly.

8. The glow pit device of claim 2 wherein the outer housing comprises at least one vertical protrusion to abut the inner housing.

9. The glow pit device of claim 8 wherein the at least one vertical protrusion comprises a first medial protrusion, and as second annular protrusion.

10. The glow pit device of claim 1 further comprising an audio output device coupled to the controller; and wherein the controller is configured to cause the audio output device to generate an audio indication.

11. The glow pit device of claim 1 wherein the at least one electronic heating assembly comprises a plurality thereof, the plurality of electronic heating assemblies being carried by the first housing in a radially spaced apart arrangement.

12. A glow pit device comprising:
a first housing to rest on a floor and having a cavity therein, and defining a plurality of annular openings;
a second housing coupled to the first housing and comprising a translucent portion; and
an electronics assembly comprising
an electronics housing carried within the first housing,
at least one electronic light source carried by the electronics housing,
an audio output device carried by the electronics housing, and
a controller carried by the electronics housing and coupled to the at least one electronic light source and the audio output device, the controller configured to
cause the at least one electronic light source to transmit visual effects through the translucent portion, and
cause the audio output device to generate an audio indication.

13. The glow pit device of claim 12 wherein the electronics assembly comprises an electronic heating assembly adjacent to the electronics housing, the electronic heating assembly comprising at least one heating device, and a thermal reflector adjacent to the at least one heating device and configured to direct thermal radiation through the plurality of annular openings; and wherein the controller is coupled to the electronic heating assembly and configured to activate the at least one heating device.

14. The glow pit device of claim 13 wherein the thermal reflector comprises an annular-shaped thermal reflector; and wherein the at least one heating device comprises a plurality of heating devices carried by the annular-shaped thermal reflector in a radially spaced apart arrangement.

15. The glow pit device of claim 12 wherein the second housing comprises an inner housing, an outer housing adjacent to the inner housing and carrying the translucent portion, and a coupling interface coupling the inner housing and the outer housing together; and wherein the second housing comprises a drain feature extending through the first housing and the second housing.

16. The glow pit device of claim 15 wherein the drain feature comprises a drain passageway extending through the first housing and the second housing, and a pipe fluidly coupled to the drain passageway and extending outwardly from the second housing.

17. The glow pit device of claim 12 wherein the at least one electronic light source is carried by an upper surface of the electronics housing.

18. A method for making a glow pit device comprising:
forming a first housing to rest on a floor, the first housing having a cavity therein, and defining a plurality of annular openings;
coupling a second housing to the first housing, the second housing comprising a translucent portion; and
positioning an electronics assembly within the first housing, the electronics assembly comprising
an electronics housing carried within the first housing,
at least one electronic light source carried by the electronics housing,
an audio output device carried by the electronics housing, and
a controller carried by the electronics housing and coupled to the at least one electronic light source and the audio output device, the controller configured to
cause the at least one electronic light source to transmit visual effects through the translucent portion, and
cause the audio output device to generate an audio indication.

19. The method of claim 18 wherein the electronics assembly comprises an electronic heating assembly adjacent to the electronics housing, the electronic heating assembly comprising at least one heating device, and a thermal reflector adjacent to the at least one heating device and configured to direct thermal radiation through the plurality of annular openings; and wherein the controller is coupled to the electronic heating assembly and configured to activate the at least one heating device.

20. The method of claim 19 wherein the thermal reflector comprises an annular-shaped thermal reflector; and wherein the at least one heating device comprises a plurality of heating devices carried by the annular-shaped thermal reflector in a radially spaced apart arrangement.
